(19) United States
(12) Patent Application Publication
(10) Pub. No.: US 2024/0202404 A1
(43) Pub. Date: Jun. 20, 2024

(54) APPARATUSES, METHODS, AND COMPUTER PROGRAM PRODUCTS FOR PREDICTING FUGITIVE LEAKS

(71) Applicant: Honeywell International Inc., Charlotte, NC (US)

(72) Inventors: Shahrul Azman Bin Zainal Abidin, Kuala Lumpur (MY); Madhukar Madhavamurthy Gundappa, Bangalore (IN); Ramesh Murugan Natarajan, Bangalore (IN)

(21) Appl. No.: 18/176,780

(22) Filed: Mar. 1, 2023

(30) Foreign Application Priority Data
Dec. 20, 2022 (IN) 202211073908

(51) Int. Cl. G06F 30/27

(52) U.S. Cl. CPC G06F 30/27

(57) ABSTRACT

Methods, apparatuses, and computer program products for predicting fugitive leaks are provided. For example, a computer-implemented method may include receiving current operating conditions data associated with current operation of one or more operational systems and generating, using a fugitive leak prediction model, fugitive leak predictions corresponding to the current operation of the one or more operational systems. The fugitive leak prediction model may be a machine learning model trained based at least in part on historical operating conditions data associated with past operation of the one or more operational systems and historical fugitive emissions data associated with the past operation of the one or more operational systems, and the fugitive leak prediction model may be configured to generate the fugitive leak predictions based at least in part on the current operating conditions data

### CROSS-REFERENCE TO RELATED APPLICATIONS

The present application claims priority to Indian Application No. 202211073908, filed Dec. 20, 2022, the contents of which are hereby incorporated herein in their entirety by reference.

### TECHNICAL FIELD

Embodiments of the present disclosure generally relate to monitoring fugitive leaks in operational systems, and specifically to predicting methane emissions intensity.

### BACKGROUND

Applicant has identified many technical challenges and difficulties associated with current solutions for monitoring fugitive leaks in operational systems. Through applied effort, ingenuity, and innovation, Applicant has solved problems relating to monitoring fugitive leaks in operational systems, which are described in detail below.

### BRIEF SUMMARY

According to one aspect, embodiments of the present invention feature an apparatus comprising at least one processor and at least one non-transitory memory comprising program code stored thereon. The at least one non-transitory memory and the program code are configured to, with the at least one processor, cause the apparatus to at least receive current operating conditions data associated with current operation of one or more operational systems, generate, using a fugitive leak prediction model, at least one fugitive leak prediction corresponding to the current operation of the one or more operational systems, and output the at least one fugitive leak prediction. The fugitive leak prediction model comprises a machine learning model trained based at least in part on historical operating conditions data associated with past operation of the one or more operational systems and historical fugitive emissions data associated with the past operation of the one or more operational systems. Additionally, the fugitive leak prediction model is configured to generate the fugitive leak predictions based at least in part on the current operating conditions data.

In some embodiments, the at least one non-transitory memory and the program code are configured to, with the at least one processor, further cause the apparatus to at least generate at least one repair alert for one or more components of the one or more operational systems based at least in part on the fugitive leak predictions. To output the at least one fugitive leak prediction the apparatus is caused to at least output the at least one repair alert.

In some embodiments, each of the fugitive leak predictions comprises one or more predicted fugitive emissions values representing predicted fugitive emissions associated with the one or more operational systems.

In some embodiments, the fugitive leak predictions are generated based at least in part on correlations between one or more sensed operating conditions values of the historical operating conditions data and one or more sensed fugitive emissions values of the historical fugitive emissions data, wherein each sensed operating conditions value of the one or more sensed operating conditions values represents an operating condition of the one or more operational systems at an instance of time during the past operation of the one or more operational systems, wherein each sensed fugitive emissions value of the one or more sensed fugitive emissions values represents fugitive emissions at an instance of time during the past operation of the one or more operational systems. The fugitive leak prediction model is trained based at least in part on the correlations.

In some embodiments, the at least one non-transitory memory and the program code are configured to, with the at least one processor, further cause the apparatus to at least train the fugitive leak prediction model based at least in part on the historical operating conditions data and the historical fugitive emissions data.

In some embodiments, the fugitive leak prediction model is trained based at least in part on simulated fugitive emissions data associated with simulated operation of the one or more operational systems, and the fugitive leak predictions are generated based at least in part on correlations between one or more simulated operating conditions values of the simulated fugitive emissions data and one or more estimated fugitive emissions values of the simulated fugitive emissions data associated with the one or more simulated operating conditions values. The fugitive leak prediction model is trained based at least in part on the correlations. Each simulated operating conditions value of the one or more simulated operating conditions values represents an operating condition of the one or more operational systems during the simulated operation of the one or more operational systems. Each estimated fugitive emissions value of the one or more estimated fugitive emissions values represents estimated fugitive emissions resulting from the one or more simulated operating conditions during the simulated operation of the one or more operational systems. The at least one non-transitory memory and the program code may be configured to, with the at least one processor, further cause the apparatus to at least generate the simulated fugitive emissions data by generating the one or more estimated fugitive emissions values based at least in part on the one or more simulated operating conditions values.

In some embodiments, the fugitive leak prediction model is trained based at least in part on historical fugitive leak data associated with the one or more operational systems. The historical fugitive leak data identifies one or more fugitive leaks detected within the one or more operational systems at one or more instances of time during the past operation of the one or more operational systems. The fugitive leak predictions may be generated based at least in part on correlations between one or more sensed operating conditions values of the historical operating conditions data corresponding to the one or more instances of time at which the one or more fugitive leaks are detected and estimated fugitive emissions values determined with respect to the one or more sensed operating conditions values. The fugitive leak prediction model may be trained based at least in part on the correlations.

In some embodiments, the historical fugitive emissions data identifies one or more sensed fugitive emissions values representing fugitive emissions sensed by one or more fugitive emissions sensors during the past operation of the one or more operational systems.

According to another aspect, embodiments of the present invention feature a method comprising receiving current operating conditions data associated with current operation of one or more operational systems, generating, using a fugitive leak prediction model, at least one fugitive leak prediction corresponding to the current operation of the one or more operational systems, and outputting the at least one fugitive leak prediction. The fugitive leak prediction model comprises a machine learning model trained based at least in part on historical operating conditions data associated with past operation of the one or more operational systems and historical fugitive emissions data associated with the past operation of the one or more operational systems. Additionally, the fugitive leak prediction model is configured to generate the fugitive leak predictions based at least in part on the current operating conditions data.

According to another aspect, embodiments of the present invention feature a computer program product comprising at least one non-transitory computer-readable storage medium having computer-readable program code portions stored therein. The computer-readable program code portions comprise an executable portion configured to: receive current operating conditions data associated with current operation of one or more operational systems, generate, using a fugitive leak prediction model, at least one fugitive leak prediction corresponding to the current operation of the one or more operational systems, and output the at least one fugitive leak prediction. The fugitive leak prediction model comprises a machine learning model trained based at least in part on historical operating conditions data associated with past operation of the one or more operational systems and historical fugitive emissions data associated with the past operation of the one or more operational systems. Additionally, the fugitive leak prediction model is configured to generate the fugitive leak predictions based at least in part on the current operating conditions data.

The above summary is provided merely for the purpose of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below. Other features, aspects, and advantages of the subject will become apparent from the description, the drawings, and the claims.

### BRIEF DESCRIPTION OF THE DRAWINGS

Having thus described the embodiments of the disclosure in general terms, reference now will be made to the accompanying drawings, which are not necessarily drawn to scale, and wherein:

FIG. 1 illustrates an exemplary block diagram of an environment in which embodiments of the present disclosure may operate;

FIG. 2 illustrates an exemplary block diagram of an example apparatus that may be specially configured in accordance with an example embodiment of the present disclosure;

FIG. 3 illustrates a visualization of an example computing environment for generating fugitive leak predictions using a fugitive leak prediction model, in accordance with at least some example embodiments of the present disclosure;

FIG. 4 illustrates a flowchart including operational blocks of an example process for generating fugitive leak predictions and performing various actions based on the generated predictions, in accordance with at least some example embodiments of the present disclosure;

FIG. 5 is an illustration of an exemplary emissions management dashboard interface of a graphical user interface, in accordance with at least some example embodiments of the present disclosure; and

FIG. 6 is an illustration of an exemplary emissions management dashboard interface of a graphical user interface, in accordance with at least some example embodiments of the present disclosure.

### DETAILED DESCRIPTION

Some embodiments of the present disclosure now will be described more fully hereinafter with reference to the accompanying drawings, in which some, but not all, embodiments of the disclosure are shown. Indeed, embodiments of the disclosure may be embodied in many different forms and should not be construed as limited to the embodiments set forth herein, rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communication circuitry, input/output circuitry, and the like. In some embodiments, other elements may provide or supplement the functionality of particular circuitry. Alternatively or additionally, in some embodiments, other elements of a system and/or apparatus described herein may provide or supplement the functionality of another particular set of circuitry. For example, a processor may provide processing functionality to any of the sets of circuitry, a memory may provide storage functionality to any of the sets of circuitry, communications circuitry may provide network interface functionality to any of the sets of circuitry, and/or the like.

The term “electronically coupled,” “electronically coupling,” “electronically couple,” “in communication with,” “in electronic communication with,” or “connected” in the present disclosure refers to two or more elements or components being connected through wired means and/or wireless means, such that signals, electrical voltage/current, data and/or information may be transmitted to and/or received from these elements or components.

For a variety of reasons, businesses may need to track emissions of greenhouse gases (GHGs) that occur during commercial/industrial activities, such as oil and natural gas production, heating, electricity generation, and manufacturing. Such greenhouse gases include, but are not limited to carbon dioxide, nitrous oxide, and methane.

One source of GHG emissions (and particularly methane emissions) are fugitive leaks, which cause unintentional and/or irregular releases of gas (e.g., from pressurized containment) known as fugitive emissions. Often, fugitive emissions are the result of fugitive leaks occurring at various components of operational systems for performing commercial/industrial activities. For example, components such as valves, pumps, and flanges of these operational systems can develop fugitive leaks as a result of normal wear and tear, damage, or defectiveness, to list a few examples. Accordingly, routine maintenance of these components can reduce the occurrence of fugitive leaks.

It is common for businesses to deploy processes for leak detection and repair (LDAR). In one example, an LDAR inspection is performed, which is normally a walk-through inspection of an operational system during which inspectors may move through an operational system with portable detection equipment (e.g., wands or sniffer devices), which is placed in close proximity to or in contact with various components of the operational system in order to detect and/or measure fugitive emissions leaking from the components. Upon completion of the inspection, an LDAR report is often issued identifying any detected fugitive leaks (e.g., satisfying a detection threshold) and providing additional details such as measurements or readings associated with the detected fugitive leaks. Often, these LDAR inspections are required by regulations. However, the inspections are relatively infrequent, occurring once annually in many cases.

Fugitive emissions sensors physically deployed within an operational system may allow for more timely monitoring of fugitive emissions. However, installation of such sensors presents challenges. Many components of operational systems may be inaccessible, making it difficult for fugitive emissions sensors to be installed closely enough to the components to effectively monitor them for fugitive emissions. Additionally, some operational systems may require installation of many such emissions sensors in order to effectively monitor the systems for fugitive leaks, making the reliance on physically installed fugitive emissions sensors potentially very costly.

It would be desirable to predict the occurrence and development of fugitive leaks on a more frequent basis (e.g., in real time or near real time) and to detect fugitive leaks before they reach the detection threshold used in LDAR inspections. More timely detection of fugitive leaks would allow for proactive monitoring of fugitive leaks and preventative maintenance to address fugitive leaks before they can develop to the point of meeting the detection threshold. Moreover, it would be desirable to develop a “soft sensor” for detecting fugitive leaks that can accurately predict the occurrence and development of fugitive leaks without the need for “hard sensors” physically installed in close proximity to the various components being monitored for leaks.

Various embodiments of the present disclosure provide for generating accurate and precise fugitive leak predictions to enable more timely and less resource-intensive tracking and remediation of fugitive leaks. In example embodiments, fugitive leak predictions for an operational system are generated based on current operating conditions data and historical leak data, historical operating conditions data, and/or historical fugitive emissions data for the operational system. In one example, historical operating conditions data can be correlated with fugitive leaks identified in one or more LDAR reports and/or fugitive emissions data generated by fugitive emissions sensors in order to develop a model for predicting fugitive emissions based on current operating conditions data. Moreover, various embodiments of the present disclosure provide for generating simulated emissions data and/or simulated operating conditions data, for example, in order to develop a training data set for training a machine learning model to predict fugitive leaks that is more comprehensive than the available historical data.

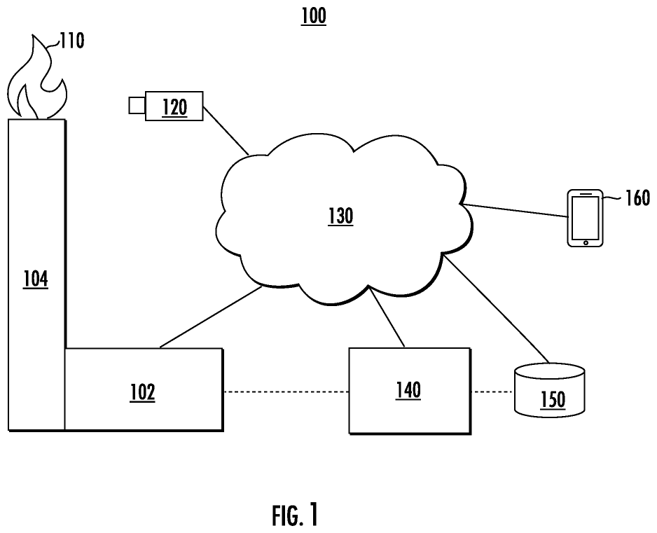

FIG. 1 illustrates an exemplary block diagram of an environment 100 in which embodiments of the present disclosure may operate. Specifically, FIG. 1 illustrates an operational system 102, which, for the purposes of illustration is depicted as a plant that may be associated with a flare stack 104 (“stack 104”). In some embodiments, the stack 104 is embodied as part of the plant 102, for example as a processing unit thereof. The stack 104 may be used to flare and/or vent one or more gases. These gases may include, but are not limited to, greenhouse gases. Flaring of gases may generate a flame 110. The flame 110 of a stack 104 may be observed, measured, analyzed by, and/or the like by one or more sensors 120 in accordance with operations and/or functions described herein. One or more sensors 120 may generate and/or transmit sensor data across a network 130 to an operations processing system 140. The operations processing system 140 may be electronically and/or communicatively coupled to one or more operational systems, for example one or more of the operational system 102, one or more databases 150, and one or more user devices 160. In some embodiments, the operational system 102 embodies or includes a different type of processing plant, and/or does not include the flare stack 104. For example, in some embodiments, the operational system 102 includes any number of processing units that each perform different tasks for producing a final product (e.g., a blended, constructed, or otherwise combined product) from one or more input ingredients.

The operational system 102 may, for example, be a processing plant that receives and processes ingredients as inputs to create a final product, such as a hydrocarbon processing plant. The operational system 102 may generate waste gasses. In various embodiments, waste gasses may be released to atmosphere, such as through a stack 104. Alternatively, waste gases may be flared when being released to atmosphere. Additionally, or alternatively, flaring and venting of gases may occur at locations other than a stack 104. Additionally, quantities of gases at other locations may unintentionally escape into the atmosphere as fugitive emissions through fugitive leaks. In some embodiments, locations where gases may unintentionally be released (e.g., through fugitive leaks) may include components of the operational system 102 such as flanges, pumps, well heads, safety release valves, pipe headers, and/or the like.

The operational system 102 in some embodiments includes any number of individual processing units. The processing units may each embody an asset of the operational system 102 that performs a particular function during operation of the operational system 102. For example in the example context of a particular oil refinery embodying the operational system 102, the processing units may include a crude processing unit, a hydrotreating unit, an isomerization unit, a vapor recovery unit, a catalytic cracking unit, a aromatics reduction unit, a visbreaker unit, a storage tank, a blender, and/or the like that perform a particular operation for transforming, storing, and/or otherwise handling one or more input ingredient(s). In some embodiments, each individual unit embodying a component of the operational system 102 is associated with a determinable location. The determinable location of a particular unit in some embodiments represents an absolute position (e.g., GPS coordinates, latitude and longitude locations, and/or the like) or a relative position (e.g., a point representation of the location of a unit from a local origin point corresponding to the operational system 102). In some embodiments, a unit includes or otherwise is associated with a location sensor and/or software-driven location services that provide the location data representing the location corresponding to that unit. In other embodiments the location of a unit is stored and/or otherwise predetermined within a software environment, provided by a user and/or otherwise determinable to one or more systems, for example including the operations processing system 140.

Additionally or alternatively, in some embodiments, the operational system 102 itself is associated with a determinable location. The determinable location of the operational system 102 in some embodiments represents an absolute position (e.g., GPS coordinates, latitude and longitude locations, an address, and/or the like) or a relative position of the plant (e.g., an identifier representing the location of the operational system 102 as compared to one or more other plants, an enterprise headquarters, or general description in the world for example based at least in part on continent, state, or other definable region). In some embodiments, the operational system 102 includes or otherwise is associated with a location sensor and/or software-driven location services that provide the location data corresponding to the operational system 102. In other embodiments, the location of the operational system 102 is stored and/or otherwise determinable to one or more systems, for example including the operations processing system 140.

The flame 110 may be associated with flaring. Flaring involves the igniting and burning of concentrations of flammable gases. A gas may be comprised of a plurality of concentrations of individual gases, and some of these concentrations of individual gases may be flammable. Alternatively, a gas may be comprised of a concentration of an individual gas, which may or may not be flammable. In some embodiments, a gas may contain greenhouse gases, such as hydrocarbons. The hydrocarbons may be ignited by an ignition source, such as a pilot flame, when the gas passes by the ignition source. The ignited gas(es) may be referred to as flares, and this process may be referred to as flaring. In various embodiments, flaring may occur at the flare stack 104, which may be at a high level of elevation from one or more other components of a operational system 102, process area, piping, and the like associated with a site.

In embodiments with gases comprising hydrocarbons, the flaring of hydrocarbons will include lower emissions than the venting of the same gas(es). This is because flaring converts the hydrocarbons in the gas(es) to CO₂ and water while venting does not change the composition of the waste gas to water. Thus the flaring may reduce the emissions of hydrocarbons into the atmosphere. In contrast to flaring, venting does not use combustion and, instead, is a direct release of gas(es) to the atmosphere. While FIG. 1 illustrates a flame 110, it will also be appreciated that by removing or omitting an ignition source, such as a pilot flame, gas(es) may be vented without flaring.

The one or more sensors 120 may include sensors to detect, measure, and/or analyze data associated with operation of one or more plant(s), for example the operational system 102. In one such example context, the sensors detect, measure, and/or analyze a flame 110 and/or a gas emission, for example associated with a flaring, a venting, and/or an unintentional leaking. In some embodiments, sensors may include a camera, which may be configured to capture images and/or video in one or more spectrums of light. For example, a camera may be configured to capture images and/or video in the visible spectrum. Additional, and/or alternatively, a camera may be configured to capture images and/or video in the infrared spectrum. It will be appreciated that any number of sensor(s), sensor type(s), and/or the like may be utilized to monitor operations of a particular plant, and/or multiple plant(s). For example, the operational system 102 may comprise one or more sensors 120 for detecting or sensing various operating conditions of the operational system 102 and/or generating operating conditions data indicative of the detected or sensed operating conditions. These sensors 120 for detecting or sensing operating conditions may include temperature sensors, pressure sensors, flow rate sensors, and/or composition sensors, for determining, respectively, temperature, pressure, flow rate, and/or composition of, in proximity to, and/or within various components of the operational system 102 and/or of materials (e.g., process ingredients, products) contained within, moving through, being processed by, and/or being produced by the operational system 102.

In some embodiments, a sensor of the sensors 120 (e.g., a camera) may be configured to perform or execute one or more operations and/or functions with determining a type, quantity, and/or volume of gas flared and/or emitted. For example, a camera may capture both visible light and infrared light to generate images and/or video of flaring. Based on these images and/or video of flaring, the camera may determine a type of gas being in a flame 110 as well as a volume of gas flared. In another example with a gas emission that is vented and/or leaked and not flared, a camera may capture both visible light and infrared light to generate images and/or video of venting and/or leaking. Based on these images and/or video of venting, the camera may determine a type of gas being in a flame 110 as well as a volume of gas vented and/or leaked. In various embodiments, a sensor of the sensors 120 may generate sensor data (e.g., a camera generating images and/or video) and transmit the sensor data over a network 130. In one example, the operational system 102 may comprise one or more sensors 120 for measuring fugitive emissions and generating fugitive emissions data indicating the fugitive emissions measurements.

The network 130 may be embodied in any of a myriad of network configurations. In some embodiments, the network 130 may be a public network (e.g., the Internet). In some embodiments, the network 130 may be a private a private network (e.g., an internal localized, or closed-off network between particular devices). In some other embodiments, the network 130 may be a hybrid network (e.g., a network enabling internal communications between particular connected devices and external communications with other devices). In various embodiments, the network 130 may include one or more base station(s), relay(s), router(s), switch(es), cell tower(s), communications cable(s), routing station(s), and/or the like. In various embodiments, components of the environment 100 may be communicatively coupled to transmit data to and/or receive data from one another over the network 130. Such configuration(s) include, without limitation, a wired or wireless Personal Area Network (PAN), Local Area Network (LAN), Metropolitan Area Network (MAN), Wide Area Network (WAN), and/or the like.

The operations processing system 140 may be located remotely or in proximity of a particular plant, for example the operational system 102. In this regard, in some embodiments, the operations processing system 140 may be located remotely or in proximity to the emissions sources, such as flame 110. In some embodiments, the operations processing system 140 is configured via hardware, software, firmware, and/or a combination thereof, to perform data intake of one or more types of data associated with one or more plant(s), for example the operational system 102. Additionally or alternatively, in some embodiments, the operations processing system 140 is configured via hardware, software, firmware, and/or a combination thereof, to generate and/or transmit command(s) that control, adjust, or otherwise impact operations of a particular plant or specific component(s) thereof, for example for controlling one or more operations of the operational system 102. Additionally or alternatively still, in some embodiments, the operations processing system 140 is configured via hardware, software, firmware, and/or a combination thereof, to perform data reporting and/or other data output process(es) associated with monitoring or otherwise analyzing operations of one or more processing plant(s), for example for generating and/or outputting report(s) corresponding to the operations performed via the operational system 102. For example, in various embodiments, the operations processing system 140 may be configured to execute and/or perform one or more operations and/or functions described herein.

The one or more databases 150 may be configured to receive, store, and/or transmit data. In some embodiments, the one or more databases 150 store data associated with multiple individual plant(s), for example multiple plants associated with the same enterprise entity but located in different geographic locations across the world. In various embodiments, the one or more databases 150 may be associated with and/or configured to store historical and/or current (e.g., real-time) operating conditions data (e.g., including sensor data) for one or more operational system 102, fugitive emissions data, simulated data (e.g., including simulated fugitive emissions data and/or simulated operating conditions data), and/or fugitive leak data (e.g., including or based on LDAR reports).

The one or more user devices 160 may be associated with users of the operations processing system 140. In various embodiments, the operations processing system 140 may generate and/or transmit a message, alert, or indication to a user via a user device, for example a user device of the user devices 160. Additionally, or alternatively, a user device, for example a user device of the user devices 160, may be utilized by a user to remotely access a operations processing system 140. This may be by, for example, an application operating on the user device, for example a user device of the user devices 160. A user may access the operations processing system 140 remotely, including one or more visualizations, reports, and/or real-time displays.

Additionally, while FIG. 1 illustrates certain components as separate, standalone entities communicating over the network 130, various embodiments are not limited to this configuration. In other embodiments, one or more components may be directly connected and/or share hardware or the like. For example, in some embodiments, the operations processing system 140 may include one or more databases 150, which may collectively be located in or at the operational system 102.

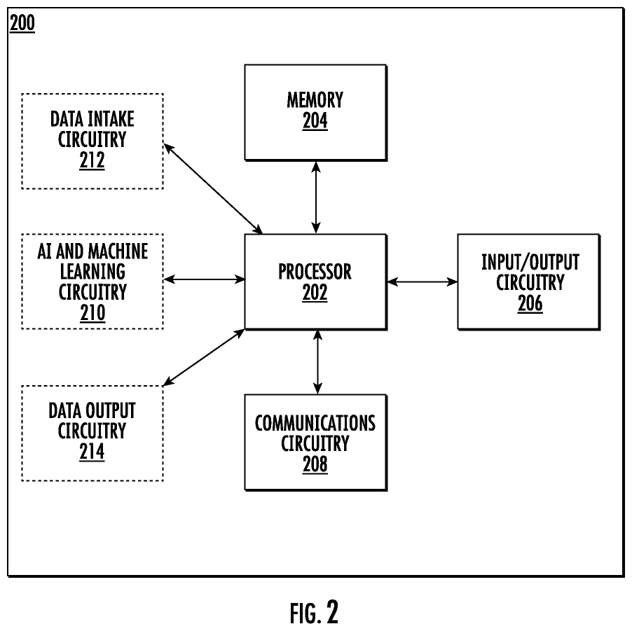

FIG. 2 illustrates an exemplary block diagram of an example apparatus that may be specially configured in accordance with an example embodiment of the present disclosure. Specifically, FIG. 2 depicts an example computing apparatus 200 (“apparatus 200”) specially configured in accordance with at least some example embodiments of the present disclosure. Examples of an apparatus 200 may include, but is not limited to, a sensor of the sensors 120, an operations processing system 140, databases 150, and/or a user device, for example a user device of the user devices 160. The apparatus 200 includes processor 202, memory 204, input/output circuitry 206, communications circuitry 208, and/or optional artificial intelligence (“AI”) and machine learning circuitry 210. In some embodiments, the apparatus 200 is configured to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

In various embodiments, a device, system, or apparatus, such as apparatus 200 of an operations processing system 140 or of a user device, for example a user device of the user devices 160, may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 200 embodies a particular, specially configured computing entity transformed to enable the specific operations described herein and provide the specific advantages associated therewith, as described herein.

Processor 202 or processor circuitry 202 may be embodied in a number of different ways. In various embodiments, the use of the terms “processor” should be understood to include a single core processor, a multi-core processor, multiple processors internal to the apparatus 200, and/or one or more remote or “cloud” processor(s) external to the apparatus 200. In some example embodiments, processor 202 may include one or more processing devices configured to perform independently. Alternatively, or additionally, processor 202 may include one or more processor(s) configured in tandem via a bus to enable independent execution of operations, instructions, pipelining, and/or multithreading.

In an example embodiment, the processor 202 may be configured to execute instructions stored in the memory 204 or otherwise accessible to the processor. Alternatively, or additionally, the processor 202 may be configured to execute hard-coded functionality. As such, whether configured by hardware or software methods, or by a combination thereof, processor 202 may represent an entity (e.g., physically embodied in circuitry) capable of performing operations according to embodiments of the present disclosure while configured accordingly. Alternatively, or additionally, processor 202 may be embodied as an executor of software instructions, and the instructions may specifically configure the processor 202 to perform the various algorithms embodied in one or more operations described herein when such instructions are executed. In some embodiments, the processor 202 includes hardware, software, firmware, and/or a combination thereof that performs one or more operations described herein.

In some embodiments, the processor 202 (and/or co-processor or any other processing circuitry assisting or otherwise associated with the processor) is/are in communication with the memory 204 via a bus for passing information among components of the apparatus 200.

Memory 204 or memory circuitry embodying the memory 204 may be non-transitory and may include, for example, one or more volatile and/or non-volatile memories. In some embodiments, the memory 204 includes or embodies an electronic storage device (e.g., a computer readable storage medium). In some embodiments, the memory 204 is configured to store information, data, content, applications, instructions, or the like, for enabling an apparatus 200 to carry out various operations and/or functions in accordance with example embodiments of the present disclosure.

Input/output circuitry 206 may be included in the apparatus 200. In some embodiments, input/output circuitry 206 may provide output to the user and/or receive input from a user. The input/output circuitry 206 may be in communication with the processor 202 to provide such functionality. The input/output circuitry 206 may comprise one or more user interface(s). In some embodiments, a user interface may include a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more operations and/or functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a computing device and/or other display associated with a user.

Communications circuitry 208 may be included in the apparatus 200. The communications circuitry 208 may include any means such as a device or circuitry embodied in either hardware or a combination of hardware and software that is configured to receive and/or transmit data from/to a network and/or any other device, circuitry, or module in communication with the apparatus 200. In some embodiments the communications circuitry 208 includes, for example, a network interface for enabling communications with a wired or wireless communications network. Additionally or alternatively, the communications circuitry 208 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 208 may include circuitry for interacting with an antenna(s) and/or other hardware or software to cause transmission of signals via the antenna(s) and/or to handle receipt of signals received via the antenna(s). In some embodiments, the communications circuitry 208 enables transmission to and/or receipt of data from a user device, one or more sensors, and/or other external computing device(s) in communication with the apparatus 200.

Data intake circuitry 212 may be included in the apparatus 200. The data intake circuitry 212 may include hardware, software, firmware, and/or a combination thereof, designed and/or configured to capture, receive, request, and/or otherwise gather data associated with operations of one or more operational systems (e.g., plants). In some embodiments, the data intake circuitry 212 includes hardware, software, firmware, and/or a combination thereof, that communicates with one or more sensor(s), unit(s), and/or the like within a particular plant to receive particular data associated with such operations of the plant. The data intake circuitry 212 may support such operations for any number of individual plants. Additionally or alternatively, in some embodiments, the data intake circuitry 212 includes hardware, software, firmware, and/or a combination thereof, that retrieves particular data associated with one mor more plant(s) from one or more data repository/repositories accessible to the apparatus 200.

AI and machine learning circuitry 210 may be included in the apparatus 200. The AI and machine learning circuitry 210 may include hardware, software, firmware, and/or a combination thereof designed and/or configured to request, receive, process, generate, and transmit data, data structures, control signals, and electronic information for training and executing a trained AI and machine learning model configured to facilitating the operations and/or functionalities described herein. For example, in some embodiments the AI and machine learning circuitry 210 includes hardware, software, firmware, and/or a combination thereof, that identifies training data and/or utilizes such training data for training a particular machine learning model, AI, and/or other model to generate particular output data based at least in part on learnings from the training data. Additionally or alternatively, in some embodiments, the AI and machine learning circuitry 210 includes hardware, software, firmware, and/or a combination thereof, that embodies or retrieves a trained machine learning model, AI and/or other specially configured model utilized to process inputted data. Additionally or alternatively, in some embodiments, the AI and machine learning circuitry 210 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

Data output circuitry 214 may be included in the apparatus 200. The data output circuitry 214 may include hardware, software, firmware, and/or a combination thereof, that configures and/or generates an output based at least in part on data processed by the apparatus 200. In some embodiments, the data output circuitry 214 includes hardware, software, firmware, and/or a combination thereof, that generates a particular report based at least in part on the processed data, for example where the report is generated based at least in part on a particular reporting protocol. Additionally or alternatively, in some embodiments, the data output circuitry 214 includes hardware, software, firmware, and/or a combination thereof, that configures a particular output data object, output data file, and/or user interface for storing, transmitting, and/or displaying. For example, in some embodiments, the data output circuitry 214 generates and/or specially configures a particular data output for transmission to another sub-system for further processing. Additionally or alternatively, in some embodiments, the data output circuitry 214 includes hardware, software, firmware, and/or a combination thereof, that causes rendering of a specially configured user interface based at least in part on data received by and/or processing by the apparatus 200.

In some embodiments, two or more of the sets of circuitries 202-214 are combinable. Alternatively, or additionally, one or more of the sets of circuitry 202-214 perform some or all of the operations and/or functionality described herein as being associated with another circuitry. In some embodiments, two or more of the sets of circuitry 202-214 are combined into a single module embodied in hardware, software, firmware, and/or a combination thereof. For example, in some embodiments, one or more of the sets of circuitry, for example the AI and machine learning circuitry 210, may be combined with the processor 202, such that the processor 202 performs one or more of the operations described herein with respect the AI and machine learning circuitry 210.

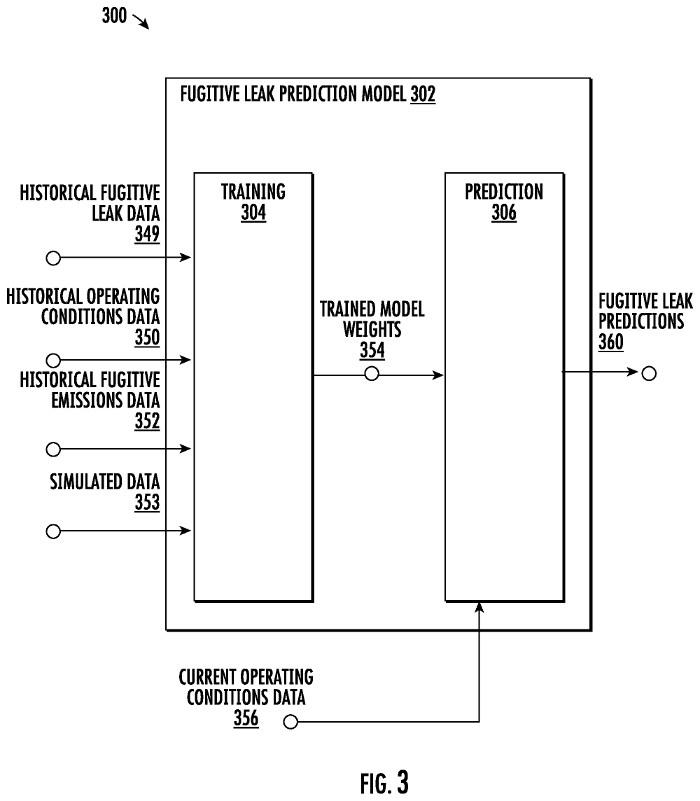

FIG. 3 illustrates a visualization of an example computing environment for generating fugitive leak predictions using a fugitive leak prediction model, in accordance with at least some example embodiments of the present disclosure. In this regard, the example computing environments and various data described associated therewith may be maintained by one or more computing devices, such as the operations processing system 140 and/or the apparatus 200. The operations processing system 140 and/or the apparatus 200, for example, may be specially configured via hardware, software, firmware, and/or a combination thereof, to perform the various data processing and interactions described with respect to FIG. 3 to generate at least one fugitive leak prediction, for example including any number of fugitive leak predictions.

In various embodiments, the operations processing system 140 and/or the apparatus 200 may be configured to generate one or more fugitive leak predictions (e.g., using a fugitive leak prediction model) for an operational system 102.

The example computing environment 300 of FIG. 3 comprises a fugitive leak prediction model 302 for generating one or more fugitive leak prediction(s), for example embodied in one or more fugitive leak predictions 360. In an example embodiment, a fugitive leak prediction model 302 uses historical and/or simulated data to generate the prediction with respect to current operating conditions data for one or more operational systems 102.

In the illustrated example, the fugitive leak prediction model 302 is configured based at least in part on a training process 304 and a prediction process 306. In some embodiments, the training process 304 is optional, and the model 302 may be previously trained and stored for use in generating fugitive leak predictions.

In various embodiments, the fugitive leak prediction model 302 may undergo a training process (e.g., represented by the training process 304) using a training data set in order to identify features and to determine optimal coefficients representing adjustment or weights to apply with respect to the features in order to produce a target fugitive emissions value reflected in the training data set, for example, based on positive and/or negative correlations between extracted features from the historical operating conditions data 350 and extracted features from the historical fugitive leak data 349 (e.g., identified fugitive leaks) and/or the historical fugitive emissions data 352 (e.g., historical fugitive emissions measurements). The fugitive leak prediction model 302 may comprise a data object created by using machine learning to learn to perform a given function (e.g., a prediction) through training with the training data set. For example, the training process may formulate a mapping function ƒ from input variables x to discrete output variables y. The fugitive leak prediction model 302 may be trained to generate a fugitive leak prediction, for example embodied in the fugitive leak predictions 360, by learning from the training data set.

In the illustrated example, the training data set input into the fugitive leak prediction model 302 at the training process 304 comprises historical data for the operational system 102, including historical fugitive leak data 349, historical operating conditions data 350, historical fugitive emissions data 352, and simulated data 353.

In general, operating conditions data for an operational system 102 may indicate various properties, detected conditions, user-configured settings, parameters, outputs, and/or measurements corresponding to operation of the operational systems, for example one or more of the operational system 102. Operating conditions data may include historical operating conditions data 350 corresponding to past operation of the operational system 102 and/or current operating conditions data such as that embodied by or included in the current operating conditions data 356. The operating conditions data may include sensor data received via sensors 120 and indicative of various operating conditions and/or values detected and/or measured during the past or current operation of the operational system 102. Operating conditions data, such as that embodied by or included in the historical operating conditions data 350 and/or the current operating conditions data 356, may identify one or more sensed operating conditions values determined by one or more operating conditions sensors of the one or more operational systems (e.g., one or more of the sensor 120) during past or current operation of the one or more operational systems. Each of the sensed operating conditions values may characterize (e.g., describe, quantify, represent) an operating condition of the one or more operational systems sensed by the one or more operating conditions sensors at an instance of time during the past or current operation of the one or more operational systems. Each of the sensed operating conditions values may be associated with a timestamp representing the instance of time associated with the sensed operating conditions value, and the one or more sensed operating conditions values identified by the operating conditions data (such as that embodied by or included in the historical operating conditions data 350 and/or the current operating conditions data 356) may include at least one of: a temperature value determined by a temperature sensor of the one or more operational systems, a pressure value determined by a pressure sensor of the one or more operational systems, a flow rate value determined by a flow rate sensor of the one or more operational systems, and a composition value determined by a composition sensor of the one or more operational systems. Additionally, each operating conditions value of the operating conditions data (such as that embodied by or included in the historical operating conditions data 350 and/or the current operating conditions data 356) may be associated with attributes (included in the operating conditions data) characterizing an operational context and/or location within the operational system relevant to the operating conditions value, including location data and/or identification data for an operating conditions sensor that generated the operating conditions value and/or for one or more components of the operational system 102 (e.g., including those located operationally upstream and/or downstream of the operating conditions sensor) and/or for the operational system 102 as a whole.

Operating conditions data (such as that embodied by or included in the historical operating conditions data 350 and/or the current operating conditions data 356) may comprise sensor data, including operating conditions data generated via the one or more sensors 120. The sensor data may include sensor data collected over relatively long periods of time such as one or more years as well as more current or recent sensor data (e.g., collected in real time). For example, operating conditions data of the historical operational data 350 or the current operating conditions data 356 may include a timestamp indicating an instance of time when each detection or measurement was taken along with sensor data (e.g., sensor values) indicative of the operating conditions at that instance of time such as temperature, pressure, flow rate, and/or composition of materials moving through and/or being processed within or by various components of the operational system 102 or of the components of the operational system 102 themselves, to list a few examples.

Fugitive emissions data (such as that embodied by or included in the historical fugitive emissions data 352 and/or current fugitive emissions data) may comprise fugitive emissions data generated via one or more sensors 120 that are specifically fugitive emissions sensors for measuring fugitive emissions produced by the operational system 102 and/or one or more particular assets and/or components thereof, including individual components of the operational system 102, parts of the individual components, groups of components, and/or the operational system 102 overall. The fugitive emissions data may include fugitive emissions data collected over relatively long periods of time such as one or more years as well as more current data (e.g., collected in real time). In one example, the fugitive emissions data may comprise a timestamp indicating an instance of time when each measurement was taken along with attributes characterizing and/or representing the fugitive emissions measurement such as fugitive emissions type and/or quantity (e.g., mass and/or volume) of gas (e.g., methane) emitted at one or more components of the operational system 102 and/or for the operational system 102 as a whole, size and/or leak rate of a fugitive leak associated with fugitive emissions measured at one or more components of the operational system 102 and/or for the operational system 102 as a whole, and/or location data and/or identification data for the one or more components of the operational system 102 and/or for the operational system 102 as a whole.

Historical fugitive emissions data (such as that embodied by or included in the historical fugitive emissions data 352) may be associated with past operation of one or more operational systems (such as that embodied by the operational system 102). The historical fugitive emissions data may identify one or more sensed fugitive emissions values. Each sensed fugitive emissions value may represent fugitive gas emissions sensed by one or more fugitive emissions sensors (e.g., such as the sensor 120) at an instance of time during past operation of the one or more operational systems. Each sensed fugitive emissions value may be associated with a timestamp representing the instance of time associated with the sensed fugitive emissions value.

Historical fugitive leak data (such as that embodied by or included in the historical fugitive leak data 349) associated with one or more operational systems may identify one or more fugitive leaks detected within the associated one or more operational systems at one or more instances of time during past operation of the one or more operational systems. Each fugitive leak of the one or more fugitive leaks identified by the historical fugitive leak data may be associated with a timestamp indicating a detection time of the fugitive leak. In some embodiments, the historical fugitive leak data may include and/or may be generated based at least in part on one or more LDAR reports resulting from one or more LDAR inspections of the operational systems.

Simulated data for one or more operational systems (such as that embodied by or included in the simulated data 353) may comprise simulated fugitive emissions data and/or simulated operating conditions data associated with simulated operation of the one or more operational systems. The simulated operating conditions data may comprise one or more simulated operating conditions values, each of which may characterize or represent an operating condition of the one or more operational systems during the simulated operation of the one or more operational systems. The simulated fugitive emissions data may comprise one or more estimated fugitive emissions values, each of which may represent estimated fugitive emissions resulting from operating conditions characterized or represented by simulated operating conditions values associated with the simulated fugitive emissions value. In other words, the simulated fugitive emissions data may indicate estimated fugitive emissions that would result from operation of the operational system 102 and/or one or more particular assets and/or components thereof under the simulated operating conditions. The simulated fugitive emissions data may be generated by a simulation process configured to receive (e.g., via user input) a virtual representation of one or more operational system 102 and/or one or more particular assets and/or components thereof and simulated operating conditions data (e.g., identifying one or more simulated operating conditions values) and, based on the received virtual representation and simulated operating conditions values, output simulated data representing results of operation of the operational system 102 and/or one or more particular assets and/or components thereof according to the simulated operating conditions values.

The simulated data output by the simulation process may comprise simulated fugitive emissions data representing estimated fugitive emissions that would result from the operation of the operational system 102 and/or one or more particular assets and/or components thereof according to the simulated operating conditions associated with the simulated fugitive emissions data. The simulated data output by the simulation process may comprise simulated operating conditions data representing estimated changes to operating conditions that would result from the simulated operation of the operational system 102 and/or one or more particular assets and/or components thereof starting from a set of initial simulated operating conditions. The simulated operating conditions data received as input by the simulation process may be preconfigured or user-configured and/or may be selected from sets of possible production parameters associated with each operational system 102 and/or one or more particular assets and/or components thereof (and/or each virtual representation of each operational system 102 and/or one or more particular assets and/or components thereof). In various embodiments, the operations processing system 140 and/or apparatus 200 may be configured to determine a domain of possible operating conditions for an operational system 102 and/or one or more particular assets and/or components thereof and/or its virtual representation and/or the virtual representation of one or more particular assets and/or components thereof, generate sets of simulated operating conditions values representative of an entirety of the domain of possible operating conditions (e.g., evenly distributed across the domain), and execute the simulation process to generate the simulated fugitive emissions data for each of the generated sets of simulated operating conditions values.

In one example, the operations processing system 140 and/or apparatus 200 may be configured to determine whether current operating conditions values (e.g., of the current operating conditions data) correspond to any historical operating conditions values indicated in the historical operating conditions data 350 (e.g., for past operation of the operational system 102 and/or one or more particular assets and/or components thereof) and, in response to determining that the current operating conditions values do not correspond to any historical operating conditions (e.g., by virtue of the operational system 102 and/or one or more particular assets and/or components thereof never having previously operated under the current operating conditions), execute the simulation process to generate the simulated fugitive emissions data for simulated operating conditions values corresponding to (e.g., matching) the current operating conditions values. In various embodiments, the operations processing system 140 and/or apparatus 200 may be configured to combine and store (as the simulated data 353) each set of simulated operating conditions values and/or data used by the simulation process and any simulated fugitive emissions data resulting from executing the simulation process with respect to the simulated operating conditions. In another example, the operations processing system 140 and/or apparatus 200 may be configured to execute the simulation process to generate simulated fugitive emissions data for simulated operating conditions values in response to determining that the historical fugitive emissions data (such as that embodied by or included in the historical fugitive emissions data 352) does not include sensed fugitive emissions values for any sensed operating conditions values corresponding to (e.g., matching) the simulated operating conditions values. In other words, in response to determining that no fugitive emissions measurements were taken at the same time and/or position as a set of operating conditions measurements (e.g., by virtue of there being no fugitive emissions sensor installed at the position and/or time), the apparatus may instead generate simulated fugitive emissions data estimating the fugitive emissions that would result from the operational system operating under the operating conditions indicated by the set of operating conditions measurements.

In one example, the training process 304 may formulate a mapping function ƒ from input variables x to discrete output variables y, with the input variables x each representing features extracted from the training data set (e.g., historical fugitive leak data 349, historical operating conditions data 350, historical fugitive emissions data 352, simulated data 353). For example, based at least in part on the training process 304, the fugitive leak prediction model 302 may be configured to express a fugitive leak prediction using a function ƒ(x₁, x₂, . . . , xₚ), where x₁, x₂, . . . , xₚ are features, quantities, values, and/or metrics extracted, calculated, and/or determined from the training data set. In particular, the features, quantities, values, and/or metrics extracted, calculated, and/or determined from the training data set may represent and/or correspond to attributes (e.g., values, quantities) reflected in the training data set with respect to a particular data item associated with the prediction being generated such as sensed or simulated operating conditions values and/or sensed or simulated fugitive emissions values. The mapping function and/or any trained model weights formulated via the training process 304 may be based at least in part on correlations between one or more sensed operating conditions values of the historical operating conditions data and one or more sensed fugitive emissions values of the historical fugitive emissions data, correlations between one or more simulated operating conditions values of the simulated fugitive emissions data and one or more estimated fugitive emissions values of the simulated fugitive emissions data associated with the one or more simulated operating conditions values, and/or correlations between one or more sensed operating conditions values of the historical operating conditions data corresponding to one or more instances of time at which one or more fugitive leaks are detected (e.g., in the historical fugitive leak data) and estimated fugitive emissions values determined with respect to the one or more sensed operating conditions values. The training process 304 may comprise determining these correlations and/or any other relationships between the various features of the training data set and configuring and/or training the fugitive leak prediction model (such as that embodied by or included in the fugitive leak prediction model 302) based at least in part on the determined correlations and/or relationships. The training process 304 may formulate mapping functions at the level of individual assets or components of an operational system 102, an operational system 102 itself, and/or groups of operational systems, for example one or more of the operational system 102, (e.g., all operational systems, for example one or more of the operational system 102, within predefined sites, all operational systems, for example one or more of the operational system 102, for all sites within predefined geographical regions, all operational systems, for example one or more of the operational system 102, across an entire enterprise).

In some embodiments, the training data set (e.g., historical fugitive leak data 349, historical operating conditions data 350, historical fugitive emissions data 352, simulated data 353) may be input into the training process 304 of the fugitive leak prediction model 302 to train the model to generate the fugitive leak predictions 360. A product of the model training are trained model weights 354 that are used by the prediction process 306 of the fugitive leak prediction model 302. In some embodiments, after an initial training, further training data (e.g., subsequently received and/or generated historical fugitive leak data 349, historical operating conditions data 350, historical fugitive emissions data 352, and/or simulated data 353) may be input to the training process 304 of the fugitive leak prediction model 302, periodically or on an on-going basis, to refine and update the model.

The fugitive leak prediction model 302 may be trained to generate a fugitive leak prediction, for example embodied in the fugitive leak predictions 360, based at least in part on an input data set.

In some embodiments, an input data set for generating the fugitive leak prediction, for example embodied in the fugitive leak predictions 360, may comprise current operating conditions data 356.

Current operating conditions data (such as that embodied by or including the current operating conditions data 356) may be operating conditions data as defined with respect to the historical operating conditions data 350. However, the current operating conditions data is associated with current operation of the operational system, whereas the historical operating conditions data is associated with past operation of the operational system. In some embodiments, the current operation of the operational system (with which the current operating conditions data is associated) may refer to a period of operation of an operational system subsequent to that described by the historical operating conditions data used to train the fugitive leak prediction model 302 and/or subsequent to training of the fugitive leak prediction model 302. In other words, current operation of the operational system (described by the current data) may be subsequent to past operation of the operational system (described by the historical data). However, the current operation of the operational system (with which the current operating conditions data is associated) may refer to any period of operation of the operational system for which a fugitive leak prediction is desired, including operation of the operational system that occurred before the past operation described by the historical operating conditions data and/or before the training of the fugitive leak prediction model.

In some embodiments, the input data set (e.g., current operating conditions data 356) is input into the prediction process 306 of the fugitive leak prediction model 302.

Upon receiving the current operating conditions data 356, the prediction process 306 of the fugitive leak prediction model 302 outputs the fugitive leak predictions 360.

In some embodiments, each fugitive leak prediction, for example embodied in the fugitive leak predictions 360, may comprise one or more predicted fugitive emissions values representing predicted fugitive emissions corresponding to (e.g., resulting from) the current operation of the one or more operational systems. For example, each of the predicted fugitive emissions values may describe a quantity associated with and/or indicative of potential fugitive emissions and/or a potential fugitive leak (e.g., amount of gas emitted, emission or leak rate, leak size) at a particular point in time. Each of the predicted fugitive emissions values associated with a particular point in time may be generated (e.g., via the fugitive leak prediction model 302) based at least in part on the current operating conditions values (e.g., of the current operating conditions data) associated with the same particular point in time. Each fugitive leak prediction may comprise a series or sequence of predicted fugitive emissions values determined for various instances of time within a period of time with which the fugitive emissions prediction is associated. In one example, the fugitive leak prediction may comprise a series or sequence of predicted fugitive emissions values for each of a plurality of instances of time beginning at an initial instance of time corresponding to a start time of a fugitive leak described by the fugitive leak prediction and culminating at a subsequent (e.g., current) instance of time. In this way, the present disclosure enables not only detecting the existence of a fugitive leak but also tracking the development and/or propagation of a detected fugitive leak over a period of time.

In some embodiments, each fugitive leak prediction, for example embodied in the fugitive leak predictions 360, may comprise identification and/or location data identifying one or more operational systems 102 and/or components thereof and/or one or more locations of or within one or more operational systems 102 and/or components thereof. For example, the fugitive leak prediction may comprise identification data identifying a particular component of an operational system 102 to which the prediction is relevant (e.g., a component inferred to be a cause of a potential fugitive leak represented by the prediction, a component associated with the current operating conditions used to generate the prediction). The fugitive leak prediction may comprise location data identifying a location of an operational system or component thereof to which the prediction is relevant (e.g., an inferred location of a potential fugitive leak represented by the prediction, a location of one or more components associated with the current operating conditions data used to generate the prediction). The identification data and/or location data may be determined based at least in part on attributes (of the current operating conditions data used to generate the prediction) characterizing the operational context and/or location within the operational system relevant to the operating conditions described in the current operating conditions data.

In some embodiments, the prediction process 306 may be configured to generate predicted fugitive emissions values representing predicted fugitive emissions corresponding to (e.g., resulting from) the current operation of a plurality of more operational systems and/or components thereof and to generate a fugitive leak prediction representing a potential fugitive leak (as embodied for example by the fugitive leak predictions 360) for each operational system and/or component thereof for which the predicted fugitive emissions values are indicative of a potential fugitive leak (e.g., the predicted fugitive emissions values exceed a leak detection threshold). In this case, the prediction process 306 may generate no fugitive leak prediction for any operational system and/or component thereof for which the predicted fugitive emissions values are not indicative of a potential fugitive leak (e.g., the predicted fugitive emissions values fail to exceed a leak detection threshold).

In some embodiments, the prediction process 306 may be configured to generate predicted fugitive emissions values representing predicted fugitive emissions corresponding to (e.g., resulting from) the current operation of a plurality of more operational systems and/or components thereof and to generate a fugitive leak prediction for all groups of operational systems, individual operational systems, and/or components thereof represented in the current operating conditions data used to generate the prediction. In this case, the fugitive leak prediction may represent an affirmative prediction of a potential fugitive leak or a negative prediction that there is no suspected fugitive leak, with the affirmative or negative prediction status represented by the actual predicted fugitive emissions values included in the prediction.

In some embodiments, each fugitive leak prediction, for example embodied in the fugitive leak predictions 360, may be associated with a selection of one or more assets, components, operational systems, for example one or more of the operational system 102, sites, and/or regions covered by the prediction and/or the current operating conditions data used to generate the prediction. Here, the fugitive leak prediction may correspond to the selected assets, components, operational systems, for example one or more of the operational system 102, sites, and/or regions, allowing granular tracking at the level of individual assets and/or components as well as overall tracking at the level of one or more operational systems, for example one or more of the operational system 102.

Having described example systems and/or apparatuses of the present disclosure, example flowcharts including various operations performed by the apparatuses and/or systems described herein will now be discussed. It should be appreciated that each of the flowcharts depicts an example computer-implemented process that may be performed by one or more of the apparatuses, systems, and/or devices described herein, for example utilizing one or more of the components thereof. The blocks indicating operations of each process may be arranged in any of a number of ways, as depicted and described herein. In some such embodiments, one or more blocks of any of the processes described herein occur in-between one or more blocks of another process, before one or more blocks of another process, and/or otherwise operates as a sun-process of a second process. Additionally or alternative, any of the processes may include some or all of the steps described and/or depicted, including one or more optional operational blocks in some embodiments. With respect to the flowcharts discussed below, one or more of the depicted blocks may be optional in some, or all, embodiments of the disclosure. Similarly, it should be appreciated that one or more of the operations of each flowchart may be combinable, replaceable, and/or otherwise altered as described herein.

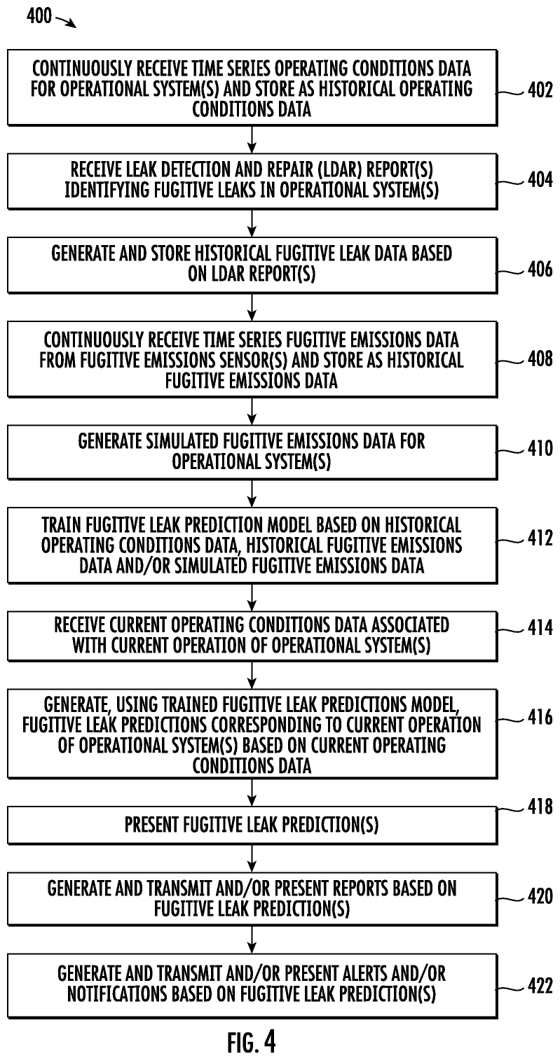

FIG. 4 illustrates a flowchart including operational blocks of an example process 400 for generating fugitive leak predictions 360, and performing various actions based at least in part on the generated predictions, in accordance with at least some example embodiments of the present disclosure. In some embodiments, the computer-implemented process of FIG. 4 is embodied by computer program code stored on a non-transitory computer-readable medium of a computer program product configured for execution to perform the computer-implemented method. Alternatively or additionally, in some embodiments, the example process 400 of FIG. 4 is performed by one or more specially configured computing devices, such as the specially configured apparatus 200 (e.g., via data intake circuitry 212, AI and machine learning circuitry 210, and/or data output circuitry 214). In this regard, in some such embodiments, the apparatus 200 is specially configured by computer program instructions stored thereon, for example in the memory 204 and/or another component depicted and/or described herein, and/or otherwise accessible to the apparatus 200, for performing the operations as depicted and described with respect to the example process of FIG. 4. In some embodiments, the specially configured apparatus 200 includes and/or otherwise is in communication with one or more external apparatuses, systems, devices, and/or the like, to perform one or more of the operations as depicted and described. While the operational blocks of the example process 400 are depicted in FIG. 4 in a particular order, this should not be understood as requiring that such operations be performed in the particular order shown or in sequential order, or that all illustrated operations be performed.

The process 400 begins at operation 402, at which an apparatus (such as, but not limited to, the apparatus 200 or circuitry thereof as described above in connection with FIG. 2) continuously receives time series operating conditions data associated with and/or from one or more operational systems, for example one or more of the operational system 102, for example the plant depicted in FIG. 1, and stores the data as historical operating conditions data (such as that embodied by or included in the historical operating conditions data 350). The received operating conditions data and/or stored historical operating conditions data may be that defined and described with respect to FIG. 3. The one or more operational systems may be one or more of the operational system 102 and may be configured to continuously gather the operating conditions data during normal operation of the operational system from and/or pertaining to the various components of the one or more operational systems and to transmit the operating conditions data to the apparatus (e.g., via the operations processing system 140 and/or one or more controllers of the one or more operational systems and/or components thereof). The historical operating conditions data may be stored in the memory 204 and/or the one or more databases 150 and/or may be associated with (e.g., describing) past operation of the one or more operational systems. In one example, the apparatus may be configured to gather, request, receive, and/or aggregate time series operating conditions data from one or more operational systems, for example one or more of the operational system 102, over a period of time and store the gathered, requested, received, and/or aggregated data as historical operating conditions data 350.

At operation 404, an apparatus (such as, but not limited to, the apparatus 200 or circuitry thereof described above in connection with FIG. 2) receives one or more leak detection and repair (LDAR) reports identifying fugitive leaks in the one or more operational systems. The LDAR reports may indicate results of one or more LDAR inspections of the one or more operational systems in the manner previously defined and described.

At operation 406, an apparatus (such as, but not limited to, the apparatus 200 or circuitry thereof described above in connection with FIG. 2) generates historical fugitive leak data based at least in part on the one or more LDAR reports received at operation 404 and stores the historical fugitive leak data (e.g., in the memory 204 and/or the one or more databases 150). The historical fugitive leak data may be that defined and described with respect to FIG. 3 and/or may be embodied by or included in the historical fugitive leak data 349. In some embodiments, operations 404 and/or 406 may be optional. For example, the historical fugitive leak data may be generated from sources other than LDAR reports. The historical fugitive leak data itself may be optional.

At operation 408, an apparatus (such as, but not limited to, the apparatus 200 or circuitry thereof as described above in connection with FIG. 2) continuously receives time series fugitive emissions data from one or more fugitive emissions sensors (e.g., one or more of the sensors 120 of the operational system 102) associated with the one or more operational systems and stores the received data as historical fugitive emissions data (such as that embodied by or included in the historical fugitive emissions data 352). The received fugitive emissions data and/or stored historical fugitive emissions data may be that defined and described with respect to FIG. 3. The one or more fugitive emissions sensors may be configured to continuously generate the fugitive emissions data during normal operation of the operational system and transmit the fugitive emissions data to the apparatus (e.g., via the operations processing system 140 and/or one or more controllers of the one or more operational systems and/or directly from the one or more fugitive emissions sensors). The historical fugitive emissions data may be stored in the memory 204 and/or the one or more databases 150 and/or may be associated with (e.g., describing) the past operation of the one or more operational systems, particularly fugitive emissions detected during the past operation. More particularly, the historical fugitive emissions data may be associated with the same past operation as that with which the historical operating conditions data and/or the historical fugitive leak data are associated. In one example, the apparatus may be configured to gather, request, receive, and/or aggregate time series fugitive emissions data from one or more fugitive emissions sensors associated with one or more operational systems, for example one or more of the operational system 102, over a period of time and store the gathered, requested, received, and/or aggregated data as historical fugitive emissions data 350.

In some embodiments, the one or more fugitive emissions sensors may be positioned and/or installed at locations within the one or more operational systems associated with the fugitive leaks identified by the historical fugitive leak data and/or the LDAR report(s). For example, the locations (e.g., positions in proximity to components identified as having fugitive leaks in the historical fugitive leak data and/or LDAR report(s)) where the various one or more fugitive emissions sensors may be installed may be determined (e.g., by the apparatus) based at least in part on the historical fugitive leak data and/or the LDAR report(s). The fugitive leak data and/or the LDAR report(s) may identify a plurality of fugitive leaks within the one or more operational systems, and a fugitive emissions sensor may be installed at a selected one or more locations and/or components identified as being associated with one of the fugitive leaks. In one example, a number of fugitive leaks having certain characteristics (e.g., being the biggest sources of fugitive emissions, meeting a predefined threshold for leak size and or fugitive emissions amount) may be selected to have fugitive emissions sensors installed, while a number of other fugitive leaks having other characteristics (e.g., being relatively small sources of fugitive emissions, failing to meet a predefined threshold for leak size and/or fugitive emissions amount) may not have fugitive emissions sensors installed. In various embodiments, the positioning of the one or more fugitive emissions sensors may be based on factors other than the fugitive leak data and/or LDAR report. For example, the one or more fugitive emissions sensors may be installed at every potential source of fugitive emissions within the one or more operational systems (e.g., at every component, at every coupling and/or fitting).

At operation 410, an apparatus (such as, but not limited to, the apparatus 200 or circuitry thereof described above in connection with FIG. 2) generates simulated data such as that embodied by or included in the simulated data 353, including simulated fugitive emissions data associated with the one or more operational systems. The simulated data generated at operation 410 may be the simulated data 353 defined and described with respect to FIG. 3 and may be generated in the manner previously described with respect to FIG. 3. For example, the apparatus may be configured to execute a simulation process with respect to a set of simulated operating conditions, which may generate the simulated data 353 to include simulated fugitive emissions data that would result from operation of an operational system 102 according to the simulated parameters. In one example, the apparatus may be configured to determine, from the historical operating conditions data and/or historical fugitive leak data, past operating conditions associated with one or more fugitive leaks identified in the fugitive leaks data and/or LDAR report(s) (e.g., past operating conditions recorded at a time period corresponding to the detection of the fugitive leak and describing operation of one or more components in physical proximity to, functionally relevant to, and/or associated with the identified fugitive leaks) and to generate the simulated fugitive emissions data based at least in part on and/or corresponding to the determined past operating conditions (which may be input into the simulation process as simulated operating conditions). Here, the apparatus may be configured to generate the simulated fugitive emissions data only for those identified fugitive leaks at which a fugitive emissions sensor was not installed. In some embodiments, operation 410 may be optional. For example, the simulated data may not be required, and/or the fugitive leak prediction model may not be required to be trained based on any simulated data.

At operation 412, an apparatus (such as, but not limited to, the apparatus 200 or circuitry thereof described above in connection with FIG. 2) trains the fugitive leak prediction model 302 based at least in part on the historical fugitive leak data 349, the historical operating conditions data 350, the historical fugitive emissions data 352, and/or the simulated data 353. The apparatus may be configured to train the model in the manner described with respect to FIG. 3, including the training process 304 defined and described with respect to FIG. 3.

At operation 414, an apparatus (such as, but not limited to, the apparatus 200 or circuitry thereof described above in connection with FIG. 2) receives current operating conditions data associated with and/or from the one or more operational systems. The received current operating conditions data may be that defined and described with respect to FIG. 3, including the current operating conditions data 356. The one or more operational systems may be one or more of the operational system 102 and may be configured to continuously gather the operating conditions data during normal operation of the operational system from and/or pertaining to the various components of the one or more operational systems and to transmit the operating conditions data to the apparatus (e.g., via the operations processing system 140 and/or one or more controllers of the one or more operational systems and/or components thereof). The received current operating conditions data may be stored in the memory 204 and/or the one or more databases 150 as part of the historical operating conditions data in addition to being used to generate the fugitive leak predictions. The received current operating conditions data may be associated with (e.g., describing) current operation of the one or more operational systems, as defined and described with respect to FIG. 3. The received current operating conditions data may be received via the same mechanisms and/or processes as the historical operating conditions data received and stored at operation 402, with the current operating conditions data being received and/or describing operation of the operational system(s) subsequent to the training of the fugitive leak prediction model based on the historical operating conditions data and/or subsequent to the past operation of the operational system(s) described by the historical operating conditions data. In one example, the apparatus may be configured to gather, request, receive, and/or aggregate time series operating conditions data from one or more operational systems, for example one or more of the operational system 102, over a period of time and store the gathered, requested, received, and/or aggregated data as historical operating conditions data 350 while passing the current operating conditions data 356 to the prediction process 306 of the fugitive leak prediction model 302.

At operation 416, an apparatus (such as, but not limited to, the apparatus 200 or circuitry thereof described above in connection with FIG. 2) generates, using a fugitive leak prediction model 302, a fugitive leak prediction, for example embodied in the fugitive leak predictions 360, corresponding to the one or more operational systems, for example one or more of the operational system 102, based at least in part on the current operating conditions data received at operation 414, the historical operating conditions data 350 received and stored at operation 402, the historical fugitive leak data generated and stored at operation 406, the historical fugitive emissions data 352 received and stored at operation 408, and/or the simulated data 353 generated at operation 410. The apparatus may be configured to generate the fugitive leak prediction, for example embodied in the fugitive leak predictions 360, using the fugitive leak prediction model 302 in the manner described with respect to FIG. 3, including the prediction process 306 defined and described with respect to FIG. 3.

In various embodiments, the apparatus may be configured to output the fugitive leak prediction(s) generated at operation 416. In some embodiments, the apparatus may output the fugitive leak prediction(s) by performing some or all of the actions described with respect to operations 418, 420, and/or 422.

At operation 418, an apparatus (such as, but not limited to, the apparatus 200 or circuitry thereof described above in connection with FIG. 2) presents the fugitive leak prediction, for example embodied in the fugitive leak predictions 360, generated at operation 416. In one example, the apparatus may be configured to present the prediction by causing the prediction to be displayed on a display of a computing device, for example, as part of a graphical user interface.

At operation 420, an apparatus (such as, but not limited to, the apparatus 200 or circuitry thereof described above in connection with FIG. 2) generates and transmits and/or presents reports based at least in part on the fugitive leak prediction, for example embodied in the methane fugitive leak predictions 360, generated at operation 416. In one example, the apparatus may be configured to receive user-configured report parameters and generate the report based at least in part on the prediction, for example embodied in the fugitive leak predictions 360, and the report parameters (e.g., by retrieving and/or generating a filtered set of data and generating a formatted report based at least in part on the report parameters, the filtered set of data comprising the fugitive leak prediction, for example embodied in the fugitive leak predictions 360, and selected data and/or information relevant to the prediction such as predicted fugitive emissions values associated with each of a selected one or more operational systems 102, components of operational systems, and/or groups of operational systems over a selected period of time).

At operation 422, an apparatus (such as, but not limited to, the apparatus 200 or circuitry thereof described above in connection with FIG. 2) generates and transmits and/or presents alerts and/or notifications based at least in part on the fugitive leak prediction, for example embodied in the fugitive leak predictions 360, generated at operation 416. In one example, the apparatus may be configured to periodically, continually, and/or continuously monitor fugitive leak predictions 360, for particular assets, components, systems, sites, regions, and/or enterprises by comparing the predictions (e.g., including the predicted fugitive emissions values) against one or more predefined leak detection thresholds (for fugitive emissions) associated with the particular assets, components, systems, sites, regions, and/or enterprises and generating the alerts and/or notifications in response to determining that a prediction, for example embodied in the fugitive leak predictions 360, meets or satisfies the one or more predefined leak detection thresholds (e.g., in response to determining that the estimated fugitive emissions values included in the predictions 360 are greater than the respective leak detection thresholds).

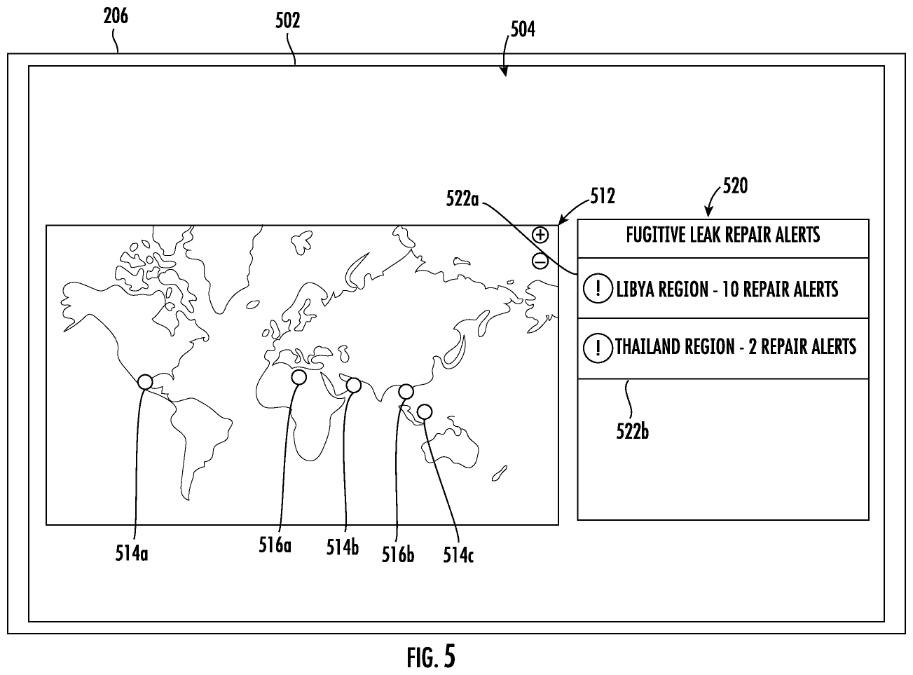

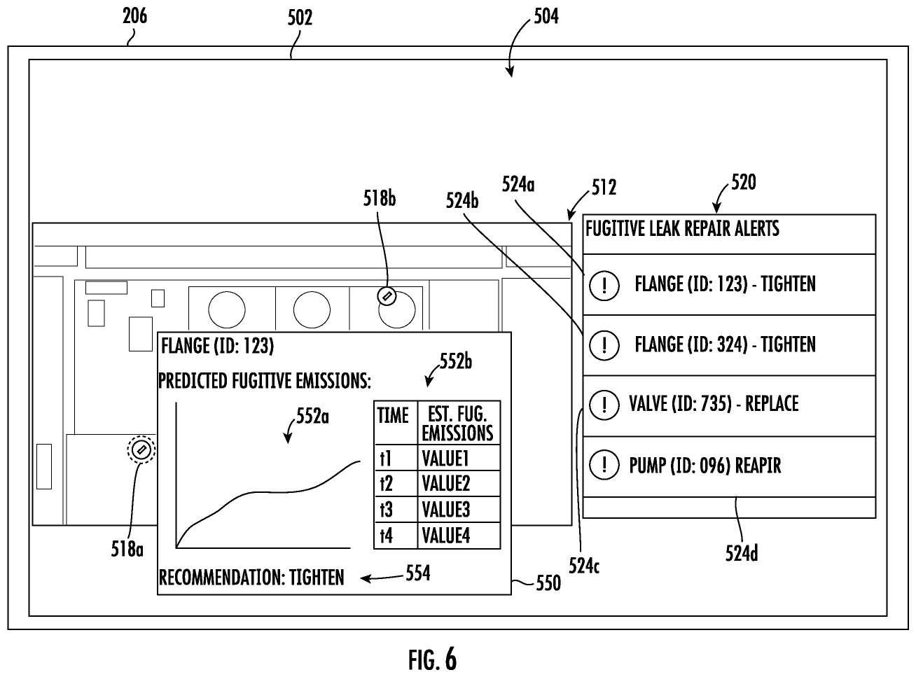

FIGS. 5 and 6 are illustrations of an exemplary fugitive leak management dashboard interface 504 of a graphical user interface (GUI) 502 presented by the apparatus 200 (e.g., via the data output circuitry 214). The fugitive leak management dashboard interface 504, including any fugitive leak predictions 360 provided as part of the dashboard, may be presented at operation 418 of the process 400 depicted in FIG. 4, for example. The GUI 502 may be rendered on a display of a computing device, for example, via the input/output circuitry 206 of the apparatus 200. The display on which the GUI 502 is rendered may be a display of the apparatus 200 or that of a user device such as the one or more user devices 160. The GUI 502 may be presented as part of a native application user interface, a user interface of a web application (e.g., rendered via a web browser application). The fugitive leak management dashboard interface 504 is used to present fugitive leak predictions 360, and other information concerning one or more operational systems, for example one or more of the operational system 102, of an enterprise. The GUI 502 comprises graphical elements arranged to form the fugitive leak management dashboard interface 504, which may be rendered on a display. The graphical elements may include textual information, shapes, graphs, tables, icons, and/or images, provided within various panes and/or windows, to list a few examples. Some of the graphical elements may, in combination, present information concerning one or more operational systems, for example one or more of the operational system 102, and/or components or assets thereof. The graphical elements may include interface elements, which are user-interactable features of the GUI 502 for receiving user input indicating selections for changing what information is presented by the emissions management dashboard interface 504 and/or how the information is presented.

More particularly, FIG. 5 is an illustration of the fugitive leak management dashboard interface 504 in an example scenario in which fugitive leak predictions (and/or information based at least in part on the fugitive leak predictions) is presented at an enterprise level (e.g., including information associated with all operational systems of a particular enterprise).

In the illustrated example, the fugitive leak management dashboard interface 504 comprises an alerts pane 520 comprising a series of alert indicators 522 and a map pane 512 comprising a series of location indicators 514 and location indicators 516.

The alerts pane 520 may be a region or portion of the GUI 502 within which one or more repair alerts may be displayed as alert indicators 522. Each of the alert indicators 522 may be a graphical element comprising a combination of icons and/or textual information representing one or more repair alerts. The one or more repair alerts may be generated based at least in part on the fugitive leak predictions 360. In one example, the one or more repair alerts may be generated in response to determining that one or more fugitive leak predictions 360 are indicative of potential fugitive leaks within the one or more operational systems associated with the enterprise. The alert indicators 522 may represent individual repair alerts of the one or more repair alerts or groups of repair alerts of the one or more repair alerts. In the illustrated example, the alerts pane 520 comprises two alert indicators 522a, 522b, each representing a group of repair alerts associated with a particular region (e.g., containing one or more operational systems to which the repair alerts pertain). A first alert indicator 522a is associated with a first region (e.g., Libya) and indicates that ten repair alerts have been generated for the first region (e.g., based on and/or in response to fugitive leak predictions generated for the first region). A second alert indicator 522b is associated with a second region (e.g., Thailand) and indicates that two repair alerts have been generated for the second region (e.g., based on and/or in response to fugitive leak predictions generated for the second region). In various embodiments, the apparatus 200 may be configured to update the alerts pane 520 continuously and/or in response to generating a new repair alert and/or a new fugitive leak prediction. In other embodiments (not illustrated), the apparatus may be configured to present the repair alerts in any suitable way, including presenting a popup window or pane overlaid on a main display region of the GUI 502 and/or transmitting one or more messages via one or more messaging systems to one or more recipients, to name a few examples.

Each of the alert indicators 522 in the alerts pane 520 may be interactable interface elements. For example, the alert indicators 522 may be selectable, and in response to selection of an alert indicator of the alert indicators 522, the apparatus may be configured to update the fugitive leak management dashboard interface 504, including the alerts pane 520 and/or the map pane 512, to present information pertaining specifically to a selected region represented by the selected alert indicator, including fugitive leak predictions generated specifically with respect to the one or more operational systems 102 within the selected region, any repair alerts based on the fugitive leak predictions for the selected region, and/or any other information for the selected region.

The map pane 512 may be a region or portion of the GUI 502 within which a map image (e.g., a graphical depiction or map of one or more geographic regions, a captured overhead image or graphical depiction of a site, a graphical depiction of an operational system 102 or a portion thereof) is displayed. The map pane 512 may comprise location indicators 514, 516, which may be graphical elements (e.g., icons) representing locations of different assets and/or components of operational systems (for example one or more of the operational system 102), different operational systems (for example one or more of the operational system 102), different sites containing the operational systems, and/or different regions containing one or more sites. The location indicators 514, 516 may be overlaid over the map image in different positions with respect to the map image, the different positions indicating locations of the objects represented by the location indicators 514, 516. For example, a position at which a location indicator of the location indicators 514, 516 is overlaid on a map image in the map pane 512 may represent the location depicted within a portion of the map image that is at or in proximity to the position where the location indicator of the location indicators 514, 516 is overlaid. Accordingly, a location indicator of the location indicators 514, 516 overlaid on a map image at a particular position may indicate that an object represented by the location indicator of the location indicators 514, 516 has a location corresponding to the location depicted within a portion of the map image at the particular position. The locations indicated by the location indicators 514, 516 may represent geographic locations (e.g., coordinates, addresses, towns, cities, counties, states, countries, continents, or any regions thereof), physical locations within a site or operational system 102, and/or schematic locations within an operational system 102, to list a few examples.

The visual appearance (e.g., size, shape, hue, brightness) of the location indicators 514, 516 displayed as part of the map pane 512 may be determined and may vary (with respect to each other) based at least in part on one or more fugitive leak predictions 360 associated with the objects represented by the location indicators 514, 516. For example, the visual appearance of a particular location indicator of the location indicators 514, 516 may be determined based at least in part on the fugitive leak prediction, for example embodied in the fugitive leak predictions 360, generated for whatever asset, component, operational system 102, and/or group of operational systems, for example one or more of the operational system 102, (e.g., within particular sites or regions) is represented by the particular location indicator of the location indicators 514, 516. More particularly, the visual appearance of the location indicators 514, 516 may be determined based at least in part on whether any repair alerts have been generated for any operational systems and/or components thereof at the locations represented by the location indicators 514, 516. For example, the location indicators 514, 516 may include green location indicators 514 and red location indicators 516. The green location indicators 514 may be icons having a green hue that represent assets, components, systems, sites, and/or regions, and locations thereof, for which no repair alerts are currently pending (e.g., by virtue of the most recent fugitive leak predictions generated for the assets, components, systems, sites, and/or regions, and locations thereof, represented by the green location indicators 514 not being indicative of any potential fugitive leaks). The red location indicators 516 may be icons having a red hue that represent assets, components, systems, sites, and/or regions, and locations thereof, for which one or more repair alerts are currently pending (e.g., by virtue of the most recent fugitive leak predictions generated for the assets, components, systems, sites, and/or regions, and locations thereof, represented by the red location indicators 514 being indicative of one or more potential fugitive leaks). In the illustrated example, the map pane 512 comprises three green location indicators 514a, 514b, 514c and two red location indicators 516a, 516b. The two red location indicators 516a, 516b may correspond respectively to the two regions represented by the repair alert indicators 522 presented in the alerts pane 520.

The location indicators 514, 516 may also be interactable interface elements. More particularly, the location indicators 514, 516 may be selectable. In one example, selection of a location indicator of the location indicators 514, 516 may cause the apparatus 200 to update the fugitive leak management dashboard interface 504 to display filtered information specific to the asset, component, system, site, and/or region represented by the selected location indicator of the location indicators 514, 516, including generating and/or retrieving a fugitive leak prediction, for example embodied in the fugitive leak predictions 360, specific to the asset, component, system, site, and/or region represented by the selected location indicator of the location indicators 514, 516 and updating the dashboard, including the alerts pane 520, to display information specific to the generated and/or retrieved prediction.

FIG. 6 is an illustration of the fugitive leak management dashboard interface 504 in an example scenario in which fugitive leak predictions (and/or information based at least in part on the fugitive leak predictions) is presented at a site level (e.g., including information associated with all operational systems of a particular site for a particular enterprise) and/or at an operational system level (e.g., including information associated with a particular operational system).

In the illustrated example, the fugitive leak management dashboard interface 504 comprises the alerts pane 520 comprising a series of repair alert indicators 524 and a map pane 512 comprising a series of repair location indicators 518.

Here, the alerts pane 520 may be similar to that defined and described with respect to FIG. 5. Now, however, the alerts pane 520 displays one or more repair alerts specifically as repair alert indicators 524. Similar to the alert indicators 522 depicted in FIG. 5, each of the repair alert indicators 524 may be a graphical element comprising a combination of icons and/or textual information representing one or more repair alerts. The one or more repair alerts may be generated based at least in part on the fugitive leak predictions 360. In one example, the one or more repair alerts may be generated in response to determining that one or more fugitive leak predictions 360 are indicative of potential fugitive leaks within a selected one or more operational systems specifically associated with the site and/or system depicted in the fugitive leak management dashboard interface 504 at the present site level. The repair alert indicators 524 may represent individual repair alerts corresponding to individual components of the selected one or more operational systems specifically associated with the site and/or system depicted in the fugitive leak management dashboard interface 504 at the present site level. In the illustrated example, the alerts pane 520 comprises four repair alert indicators 524a, 524b, 524c, 524d, each representing a particular component of an operational system. A first repair alert indicator 524a is associated with a first component (e.g., a flange having a component identifier of “123”) and indicates that a particular operation (e.g., tightening) is recommended for the first component (e.g., based on and/or in response to fugitive leak predictions generated for the first component). A second repair alert indicator 524b is associated with a second component (e.g., a flange having a component identifier of “324”) and indicates that a particular operation (e.g., tightening) is recommended for the second component (e.g., based on and/or in response to fugitive leak predictions generated for the second component). A third repair alert indicator 524c is associated with a third component (e.g., a valve having a component identifier of “735”) and indicates that a particular operation (e.g., replacement) is recommended for the third component (e.g., based on and/or in response to fugitive leak predictions generated for the third component). A fourth repair alert indicator 524d is associated with a fourth component (e.g., a pump having a component identifier of “096”) and indicates that a particular operation (e.g., repair) is recommended for the fourth component (e.g., based on and/or in response to fugitive leak predictions generated for the fourth component).

As before, in various embodiments, the apparatus 200 may be configured to update the alerts pane 520 continuously and/or in response to generating a new repair alert and/or a new fugitive leak prediction.

As before, each of the alert indicators 524 in the alerts pane 520 may be interactable interface elements. For example, the alert indicators 524 may be selectable, and in response to selection of an alert indicator of the alert indicators 524, the apparatus may be configured to update the fugitive leak management dashboard interface 504, including the alerts pane 520 and/or the map pane 512, to present information pertaining specifically to a selected component represented by the selected repair alert indicator, including fugitive leak predictions generated specifically with respect to the selected component, any repair alerts based on the fugitive leak predictions for the selected component, and/or any other information for the selected component.

The alerts pane 520 may be similar to that defined and described with respect to FIG. 5. As depicted in FIG. 6, however, the map image displayed within the map pane 512 is a graphical depiction specific to the selected one or more operational systems specifically associated with the site and/or system depicted in the fugitive leak management dashboard interface 504 at the present site level (e.g., overhead image depicting a selected site and/or a selected operational system). The map pane 512 may comprise repair location indicators 518, which may be graphical elements (e.g., icons) representing locations of different assets and/or components of the selected operational system and/or site at the present site level, particularly locations associated with pending repair alerts (e.g., such as those presented in the alerts pane 520). The repair location indicators 518 may be overlaid over the map image in different positions with respect to the map image, the different positions indicating locations of the objects represented by the location indicators 518 in a manner similar to that described with respect to the location indicators 514, 516. In the illustrated example, the map pane 512 comprises a first repair location indicator 518a at a first position with respect to the map image and a second repair location indicator 518b at a second position (e.g., different from the first position) with respect to the map image.

The repair location indicators 518 may also be interactable interface elements. More particularly, the repair location indicators 518 may be selectable. In one example, selection of a repair location indicator of the repair location indicators 514, 516 may cause the apparatus 200 to update the fugitive leak management dashboard interface 504 to display filtered information specific to the asset and/or component represented by the selected repair location indicator of the repair location indicators 518, including generating and/or retrieving a fugitive leak prediction, for example embodied in the fugitive leak predictions 360, specific to the asset and/or component represented by the selected repair location indicator and updating the dashboard, including the alerts pane 520 and possibly other panes, to display information specific to the generated and/or retrieved prediction and/or any repair alerts associated with the prediction.

In some embodiments, selection of a repair location indicator of the repair location indicators 518 may cause the apparatus 200 to update the fugitive leak management dashboard interface 504 to display a fugitive leak prediction window 550, which, in the illustrated example, is a popup window or pane overlaid over the map pane 512 at a position with respect to the map pane 512 and/or the repair location indicators 518 in proximity to a selected repair location indicator 518a. The fugitive leak prediction window 550 may present one or more fugitive leak predictions 360 and/or repair alerts associated with the particular component, asset, and/or repair alert represented by the selected repair location indicator 518a, including any predicted fugitive emissions values determined for the particular component and/or asset. The fugitive leak prediction window 550 may comprise one or more prediction graphical elements 552, which may be graphical elements representing a fugitive leak prediction and/or presenting (e.g., via graphical depictions and/or text) certain data included in the fugitive leak prediction (e.g., the estimated or predicted fugitive emissions values). In the illustrated example, the fugitive leak prediction window 550 comprises a first prediction graphical element 552a and a second prediction graphical element 552b, both of which represent a common fugitive leak prediction and/or present the same or analogous data from the fugitive leak prediction in different forms, namely in a graphical form and in a table form, respectively. The fugitive leak prediction window 550 may comprise a recommendation graphical element 554, which may be a graphical element representing a repair alert generated as a result of the fugitive leak prediction associated with the fugitive leak prediction window (e.g., that represented by the selected repair location indicator 518a). In one example, the recommendation graphical element 554 may correspond to one of the repair alert indicators 524 presented in the alerts pane 520 and may include textual information characterizing a recommended operation (e.g., tightening) to address a potential fugitive leak indicated by the fugitive leak prediction associated with the fugitive leak prediction window 550.

Although example processing systems have been described in the figures herein, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communications network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communications network. Examples of communications networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communications network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

It is to be understood that the disclosure is not to be limited to the specific embodiments disclosed, and that modifications and other embodiments are intended to be included within the scope of the appended claims. Although specific terms are employed herein, they are used in a generic and descriptive sense only and not for purposes of limitation, unless described otherwise.

What is claimed is:

1. An apparatus comprising at least one processor and at least one non-transitory memory comprising program code stored thereon, wherein the at least one non-transitory memory and the program code are configured to, with the at least one processor, cause the apparatus to at least:
receive current operating conditions data associated with current operation of one or more operational systems;
generate, using a fugitive leak prediction model, at least one fugitive leak prediction corresponding to the current operation of the one or more operational systems,
wherein the fugitive leak prediction model comprises a machine learning model trained based at least in part on historical operating conditions data associated with past operation of the one or more operational systems and historical fugitive emissions data associated with the past operation of the one or more operational systems,
wherein the fugitive leak prediction model is configured to generate the fugitive leak predictions based at least in part on the current operating conditions data; and
output the at least one fugitive leak prediction.

2. The apparatus of claim 1, wherein the at least one non-transitory memory and the program code are configured to, with the at least one processor, further cause the apparatus to at least:
generate at least one repair alert for one or more components of the one or more operational systems based at least in part on the fugitive leak predictions, wherein to output the at least one fugitive leak prediction the apparatus is caused to at least output the at least one repair alert.

3. The apparatus of claim 1, wherein each of the fugitive leak predictions comprises one or more predicted fugitive emissions values representing predicted fugitive emissions associated with the one or more operational systems.

4. The apparatus of claim 1, wherein the fugitive leak predictions are generated based at least in part on correlations between one or more sensed operating conditions values of the historical operating conditions data and one or more sensed fugitive emissions values of the historical fugitive emissions data, wherein each sensed operating conditions value of the one or more sensed operating conditions values represents an operating condition of the one or more operational systems at an instance of time during the past operation of the one or more operational systems, wherein each sensed fugitive emissions value of the one or more sensed fugitive emissions values represents fugitive emissions at an instance of time during the past operation of the one or more operational systems, and wherein the fugitive leak prediction model is trained based at least in part on the correlations.

5. The apparatus of claim 1, wherein the at least one non-transitory memory and the program code are configured to, with the at least one processor, further cause the apparatus to at least:
train the fugitive leak prediction model based at least in part on the historical operating conditions data and the historical fugitive emissions data.

6. The apparatus of claim 1, wherein the fugitive leak prediction model is trained based at least in part on simulated fugitive emissions data associated with simulated operation of the one or more operational systems, and the fugitive leak predictions are generated based at least in part on correlations between one or more simulated operating conditions values of the simulated fugitive emissions data and one or more estimated fugitive emissions values of the simulated fugitive emissions data associated with the one or more simulated operating conditions values, wherein the fugitive leak prediction model is trained based at least in part on the correlations, and
wherein each simulated operating conditions value of the one or more simulated operating conditions values represents an operating condition of the one or more operational systems during the simulated operation of the one or more operational systems, and wherein each estimated fugitive emissions value of the one or more estimated fugitive emissions values represents estimated fugitive emissions resulting from the one or more simulated operating conditions during the simulated operation of the one or more operational systems.

7. The apparatus of claim 6, wherein the at least one non-transitory memory and the program code are configured to, with the at least one processor, further cause the apparatus to at least:
generate the simulated fugitive emissions data by generating the one or more estimated fugitive emissions values based at least in part on the one or more simulated operating conditions values.

8. The apparatus of claim 1, wherein the fugitive leak prediction model is trained based at least in part on historical fugitive leak data associated with the one or more operational systems, wherein the historical fugitive leak data identifies one or more fugitive leaks detected within the one or more operational systems at one or more instances of time during the past operation of the one or more operational systems.

9. The apparatus of claim 8, wherein the fugitive leak predictions are generated based at least in part on correlations between one or more sensed operating conditions values of the historical operating conditions data corresponding to the one or more instances of time at which the one or more fugitive leaks are detected and estimated fugitive emissions values determined with respect to the one or more sensed operating conditions values, and wherein the fugitive leak prediction model is trained based at least in part on the correlations.

10. The apparatus of claim 1, wherein the historical fugitive emissions data identifies one or more sensed fugitive emissions values representing fugitive emissions sensed by one or more fugitive emissions sensors during the past operation of the one or more operational systems.

11. A computer-implemented method comprising:
receiving current operating conditions data associated with current operation of one or more operational systems;
generating, using a fugitive leak prediction model, at least one fugitive leak prediction corresponding to the current operation of the one or more operational systems,
wherein the fugitive leak prediction model comprises a machine learning model trained based at least in part on historical operating conditions data associated with past operation of the one or more operational systems and historical fugitive emissions data associated with the past operation of the one or more operational systems,
wherein the fugitive leak prediction model is configured to generate the fugitive leak predictions based at least in part on the current operating conditions data; and
outputting the at least one fugitive leak prediction.

12. The method of claim 11, further comprising generating at least one repair alert for one or more components of the one or more operational systems based at least in part on the fugitive leak predictions and outputting the at least one fugitive leak prediction by at least outputting the at least one repair alert.

13. The method of claim 11, wherein each of the fugitive leak predictions comprises one or more predicted fugitive emissions values representing predicted fugitive emissions associated with the one or more operational systems.

14. The method of claim 11, wherein the fugitive leak predictions are generated based at least in part on correlations between one or more sensed operating conditions values of the historical operating conditions data and one or more sensed fugitive emissions values of the historical fugitive emissions data, wherein each sensed operating conditions value of the one or more sensed operating conditions values represents an operating condition of the one or more operational systems at an instance of time during the past operation of the one or more operational systems, wherein each sensed fugitive emissions value of the one or more sensed fugitive emissions values represents fugitive emissions at an instance of time during the past operation of the one or more operational systems, and wherein the fugitive leak prediction model is trained based at least in part on the correlations.

15. The method of claim 11, wherein the at least one non-transitory memory and the program code are configured to, with the at least one processor, further cause the apparatus to at least:
train the fugitive leak prediction model based at least in part on the historical operating conditions data and the historical fugitive emissions data.

16. The method of claim 11, wherein the fugitive leak prediction model is trained based at least in part on simulated fugitive emissions data associated with simulated operation of the one or more operational systems, and the fugitive leak predictions are generated based at least in part on correlations between one or more simulated operating conditions values of the simulated fugitive emissions data and one or more estimated fugitive emissions values of the simulated fugitive emissions data associated with the one or more simulated operating conditions values, wherein the fugitive leak prediction model is trained based at least in part on the correlations, and
wherein each simulated operating conditions value of the one or more simulated operating conditions values represents an operating condition of the one or more operational systems during the simulated operation of the one or more operational systems, and wherein each estimated fugitive emissions value of the one or more estimated fugitive emissions values represents estimated fugitive emissions resulting from the one or more simulated operating conditions during the simulated operation of the one or more operational systems.

17. The method of claim 16, further comprising generating the simulated fugitive emissions data by generating the one or more estimated fugitive emissions values based at least in part on the one or more simulated operating conditions values.

18. The method of claim 11, wherein the fugitive leak prediction model is trained based at least in part on historical fugitive leak data associated with the one or more operational systems, wherein the historical fugitive leak data identifies one or more fugitive leaks detected within the one or more operational systems at one or more instances of time during the past operation of the one or more operational systems.

19. The method of claim 18, wherein the fugitive leak predictions are generated based at least in part on correlations between one or more sensed operating conditions values of the historical operating conditions data corresponding to the one or more instances of time at which the one or more fugitive leaks are detected and estimated fugitive emissions values determined with respect to the one or more sensed operating conditions values, and wherein the fugitive leak prediction model is trained based at least in part on the correlations.

20. A computer program product comprising at least one non-transitory computer-readable storage medium having computer-readable program code portions stored therein, the computer-readable program code portions comprising an executable portion configured to:
receive current operating conditions data associated with current operation of one or more operational systems;
generate, using a fugitive leak prediction model, at least one fugitive leak prediction corresponding to the current operation of the one or more operational systems,
wherein the fugitive leak prediction model comprises a machine learning model trained based at least in part on historical operating conditions data associated with past operation of the one or more operational systems and historical fugitive emissions data associated with the past operation of the one or more operational systems,
wherein the fugitive leak prediction model is configured to generate the fugitive leak predictions based at least in part on the current operating conditions data; and
output the at least one fugitive leak prediction.
